(19) United States
(12) Patent Application Publication
(10) Pub. No.: US 2025/0364334 A1
(43) Pub. Date: Nov. 27, 2025

(54) ABNORMALITY DETECTION APPARATUS AND ABNORMALITY DETECTION METHOD

(71) Applicant: Hitachi High-Tech Corporation, Minato-ku, Tokyo (JP)

(72) Inventors: Yasuhide MORI, Tokyo (JP); Prashant Kumar SHARMA, Tokyo (JP); Masaki HAMAMOTO, Tokyo (JP); Takeshi OHMORI, Tokyo (JP)

(21) Appl. No.: 18/691,713

(22) PCT Filed: Feb. 21, 2023
(86) PCT No.: PCT/JP2023/006212

§ 371 Date: Mar. 13, 2024

(51) Int. Cl. H01L 21/66; H01L 21/461

(52) U.S. Cl. CPC H01L 22/20; H01L 21/461

(57) ABSTRACT

An abnormality detection apparatus including: a processing shape prediction unit configured to predict, using a processing result prediction model in which a control parameter value of the processing apparatus and an observation parameter value obtained by observing a phenomenon occurring in the processing apparatus during the processing are set as an independent variable and an evaluation value of the processing by the processing apparatus is set as a dependent variable, the evaluation value of the processing by the processing apparatus; and a first abnormality detection unit configured to detect, based on a difference between an evaluation value of determination target processing and a prediction evaluation value of the determination target processing predicted by inputting a control parameter value used in the determination target processing and an observation parameter value observed in the determination target processing to the processing result prediction model, an abnormality in the processing result.

### TECHNICAL FIELD

The invention relates to an abnormality detection apparatus and an abnormality detection method.

### BACKGROUND ART

By processing a semiconductor sample under an appropriate processing condition in a semiconductor process, desirable semiconductor processing can be performed. In recent years, new materials constituting a device are introduced, a device structure becomes complicated, a control range of a semiconductor processing apparatus is expanded, and a number of control parameters is added. The process becomes a multi-step process, and fine and complicated processing is implemented. In order to produce a high-performance device by using a semiconductor processing apparatus, it is necessary to perform process development to derive an appropriate processing condition for obtaining a target processing shape of a semiconductor sample.

PTL 1 discloses a technique of generating a prediction model indicating a relationship between a processing condition provided to a semiconductor processing apparatus and a processing result of the semiconductor processing apparatus, and estimating a condition for outputting a target value of the processing result using the prediction model.

### CITATION LIST

### Patent Literature

PTL 1: JP2019-40984A

### SUMMARY OF INVENTION

### Technical Problem

There may be a discrepancy between a processing shape estimated under a certain processing condition using the prediction model as shown in PTL 1 and a processing shape obtained by actually processing a semiconductor sample under the processing condition by the semiconductor processing apparatus. In this case, there are two conceivable causes. A first cause is that accuracy of the prediction model may be insufficient. In this case, it is necessary to improve the accuracy of the prediction model by adding training data. A second cause is that an abnormality may occur in a processing step by the semiconductor processing apparatus, and accordingly, a desired processing result cannot be obtained.

Even when training data including an experimental result in the latter case is used for training the prediction model, there is no problem since it is conceivable that the training proceeds in a direction in which irregular training data is finally ignored as an exceptional event. However, for this reason, it is necessary to train the prediction model with more training data.

Repetition of processing tests by the semiconductor processing apparatus greatly influences a cost and a period of process development. Therefore, it is desirable to exclude, from the training data, an experimental result in which a processing abnormality occurs in the semiconductor processing apparatus.

### Solution to Problem

An abnormality detection apparatus according to an embodiment of the invention is an abnormality detection apparatus configured to determine whether there is any abnormality in a processing result obtained by processing a sample by a processing apparatus, the abnormality detection apparatus including: a processing shape prediction unit configured to predict, using a processing result prediction model in which a control parameter value of the processing apparatus and an observation parameter value obtained by observing a phenomenon occurring in the processing apparatus during the processing by the processing apparatus are set as an independent variable and an evaluation value of the processing by the processing apparatus is set as a dependent variable, the evaluation value of the processing by the processing apparatus; and a first abnormality detection unit configured to detect, based on a difference between an evaluation value of determination target processing and a prediction evaluation value of the determination target processing predicted by inputting a control parameter value used in the determination target processing and an observation parameter value observed in the determination target processing to the processing result prediction model, an abnormality in the processing result of the processing apparatus.

### Advantageous Effects of Invention

A prediction model for predicting processing of a processing apparatus can learn (be trained) with less training data. Other problems and novel features will become apparent from the description of the specification and the accompanying drawings.

### BRIEF DESCRIPTION OF DRAWINGS

FIG. 1A is a system configuration diagram of an abnormality detection system.

FIG. 1B is a hardware configuration diagram of an abnormality detection apparatus.

FIG. 1C shows data and programs stored in a storage apparatus.

FIG. 2A is a functional block diagram of the abnormality detection apparatus in a training step.

FIG. 2B is a functional block diagram of the abnormality detection apparatus in an abnormality detection step.

FIG. 3 is a data structure example of processing recipe data.

FIG. 4 is a data structure example of observation data.

FIG. 5 is a data structure example of experimental result data.

FIG. 6 is a data structure example of prediction result data.

FIG. 7 is a data structure example of normal degree-of-contribution data.

FIG. 8 is an overall flowchart of abnormality detection.

FIG. 9 is a flow for calculating a shape abnormality score of verification data.

FIG. 10 is a flow for calculating a degree-of-contribution abnormality score of the verification data.

FIG. 11 is a data structure example of knowledge data.

FIG. 12 is an example of a GUI.

### DESCRIPTION OF EMBODIMENTS

Hereinafter, a preferred embodiment of the invention will be described with reference to the drawings.

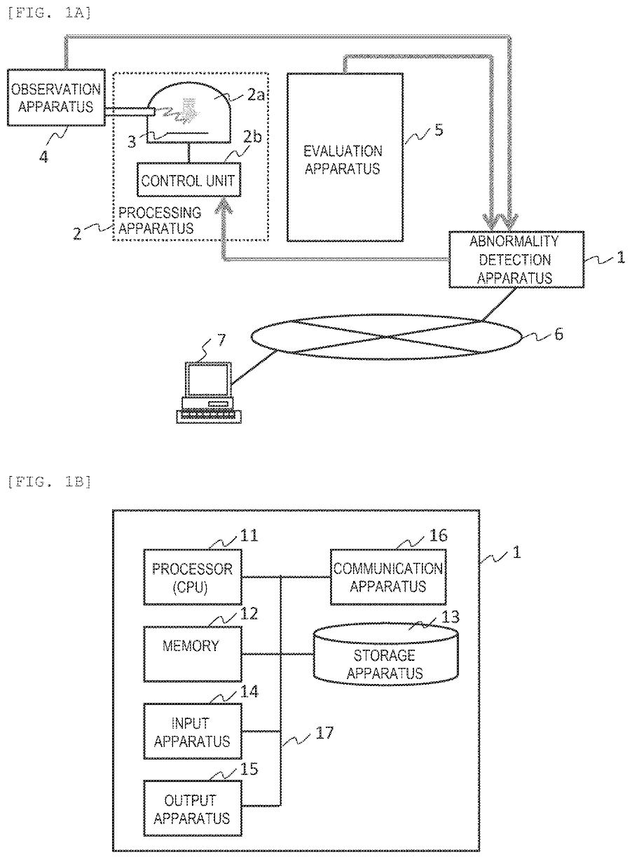

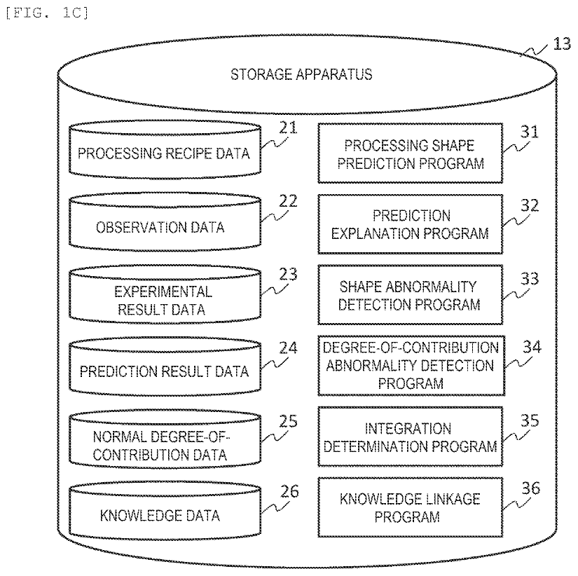

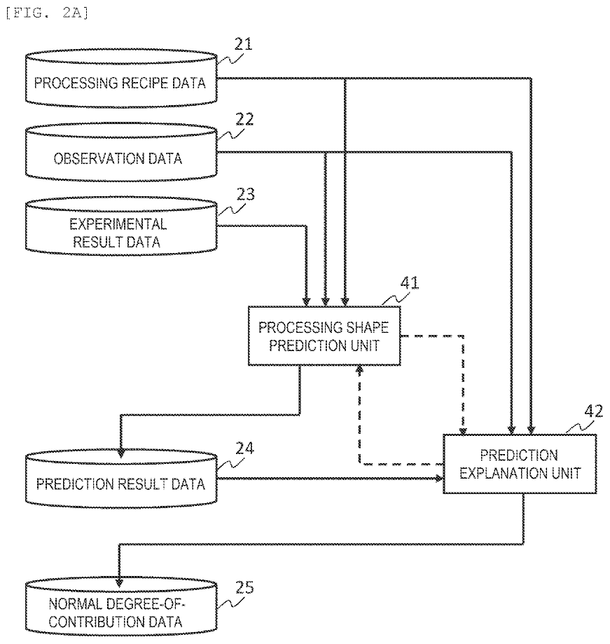

FIG. 1A shows a system configuration diagram of an abnormality detection system. Hereinafter, the present system will be described with reference to an example in which the system is used for process development of a semiconductor or a semiconductor device including a semiconductor. In the process development, an appropriate processing condition for implementing a target, for example, a desired processing shape is derived for a semiconductor processing apparatus that processes a semiconductor sample.

A processing apparatus 2 is an apparatus that processes the semiconductor sample. Processing contents of the processing apparatus 2 are not limited. Examples thereof include a lithography apparatus, a film forming apparatus, a pattern processing apparatus, an ion implantation apparatus, and a cleaning apparatus. The lithography apparatus includes an exposure apparatus, an electron beam drawing apparatus, and an X-ray drawing apparatus. The film forming apparatus includes chemical vapor deposition (CVD), physical vapor deposition (PVD), an evaporation deposition apparatus, a sputtering apparatus, and a thermal oxidation apparatus. The pattern processing apparatus includes a wet etching apparatus, a dry etching apparatus, an electron beam processing apparatus, and a laser processing apparatus. The ion implantation apparatus includes a plasma doping apparatus and an ion beam doping apparatus. The cleaning apparatus includes a liquid cleaning apparatus and an ultrasonic cleaning apparatus.

Hereinafter, a plasma processing apparatus that etches the semiconductor sample will be described as an example of the processing apparatus 2. In the plasma processing apparatus, a radio frequency alternating electromagnetic field is applied to a processing gas in a reactor 2a to generate plasma, thereby etching a sample 3. The etching in the reactor 2a is controlled according to a processing recipe set by a control unit 2b.

An evaluation apparatus 5 is an apparatus that evaluates processing performed on the sample 3 by the processing apparatus 2. An example thereof is a processing dimension measuring apparatus using an electron microscope, which measures a processing dimension of the sample 3 processed by the processing apparatus 2.

An observation apparatus 4 is an apparatus that observes a phenomenon occurring in the reactor 2a during processing of the sample 3 by the processing apparatus 2. The phenomenon to be observed is not limited, and can be appropriately selected according to a phenomenon acting on the sample 3 during the processing by the processing apparatus 2. Here, an example will be described in which a spectrophotometer that observes light emission of plasma in the reactor 2a is used as the observation apparatus 4.

The control unit 2b of the processing apparatus 2 performs processing (here, etching) on the sample 3 according to processing recipe data. The observation apparatus 4 observes a light emission state of the plasma in the reactor 2a during a processing period of the processing apparatus 2 and acquires observation data. After the processing by the processing apparatus 2 ends, the evaluation apparatus 5 measures the processing dimension of the sample 3 and acquires experimental result data. The processing recipe data, the acquired observation data, and the acquired experimental result data can be accessed from an abnormality detection apparatus 1, and are used for creation of a processing result prediction model that predicts a processing result of the processing apparatus and for detection and determination of an abnormality in the processing result to be described later.

A user accesses the abnormality detection apparatus 1 from a terminal 7 via a network 6 or directly from an input and output apparatus of the abnormality detection apparatus 1, and executes abnormality detection processing.

FIG. 1B shows a hardware configuration of the abnormality detection apparatus 1. The abnormality detection apparatus 1 is an information processing apparatus (computer) and has the following configuration. The abnormality detection apparatus 1 includes a processor (CPU) 11, a memory 12, a storage apparatus 13, an input apparatus 14, an output apparatus 15, and a communication apparatus 16, which are coupled by a bus 17. A graphical user interface (GUI) is implemented by the input apparatus 14, which is a keyboard or a pointing device, and a display, which is the output apparatus 15, and the user can use the apparatuses interactively via the GUI. The communication apparatus 16 is an interface for connecting to the network 6. It is also possible to display, on the terminal 7 via the network 6, the implemented GUI of the apparatuses.

The storage apparatus 13 usually includes a hard disk drive (HDD), a solid state drive (SSD), or the like, and stores a program to be executed by the abnormality detection apparatus 1, data to be processed by the program, or data of a result processed by the program. The memory 12 includes a random access memory (RAM) and temporarily stores a program, data necessary for executing the program, and the like according to a command of the processor 11. The processor 11 functions as a functional unit (functional block) that provides a predetermined function by executing a program loaded from the storage apparatus 13 to the memory 12.

The abnormality detection apparatus 1 is not necessarily implemented by one information processing apparatus, and may be implemented by a plurality of information processing apparatuses. A part or all of functions of the abnormality detection apparatus 1 may be implemented as a cloud-based application.

FIG. 1C shows data and programs stored in the storage apparatus 13. The data includes processing recipe data 21, observation data 22, experimental result data 23, prediction result data 24, normal degree-of-contribution data 25, and knowledge data 26, and the programs include a processing shape prediction program 31, a prediction explanation program 32, a shape abnormality detection program 33, a degree-of-contribution abnormality detection program 34, an integration determination program 35, and a knowledge linkage program 36, details of which will be described later.

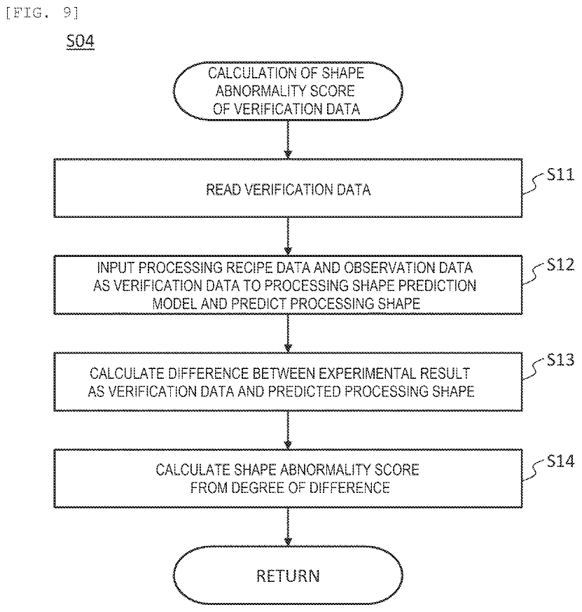

FIG. 8 shows an overall flow of abnormality detection performed by the abnormality detection apparatus 1. Steps S01 to S03 are a training step of the processing result prediction model. In the embodiment, the etching by the plasma processing apparatus is described as an example of the processing by the processing apparatus, and thus the processing result prediction model is referred to as a processing shape prediction model hereinafter to match the example. In this step, the processing shape prediction model is generated and a normal degree of contribution is calculated using normal case data. Here, the degree of contribution refers to a magnitude of contribution of each independent variable to a prediction result (dependent variable) in the processing shape prediction model. Steps S04 to S07 are an abnormality detection step of the processing result of the processing apparatus. In this step, abnormality determination of a processing result obtained according to any processing recipe is performed.

Hereinafter, each step will be described.

### (1) Step of Training

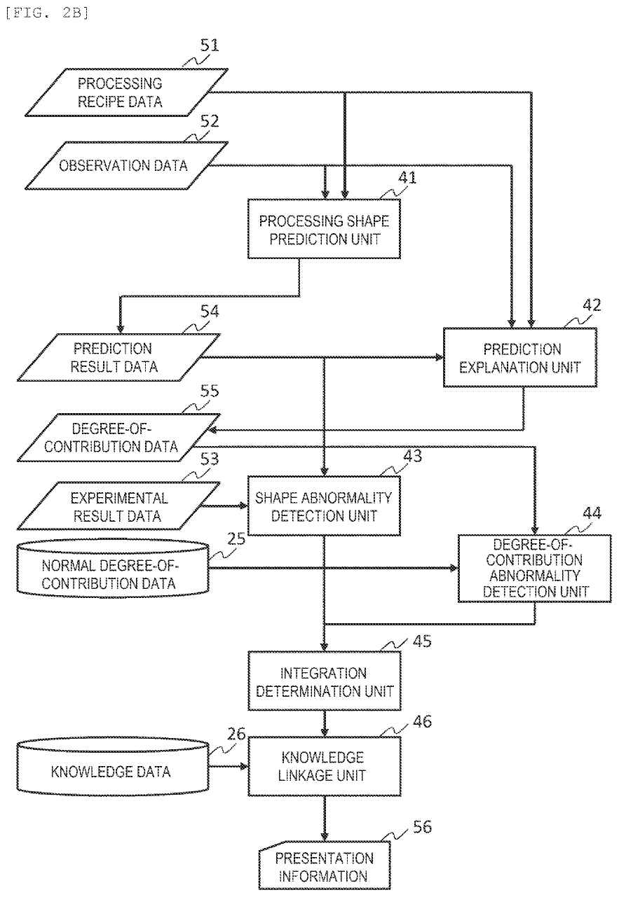

Processing of steps S01 to S03 in the overall flow (see FIG. 8) will be described. FIG. 2A shows a functional block diagram of the abnormality detection apparatus 1 in this step. A processing shape prediction unit 41 is a functional unit that functions by the processor 11 executing the processing shape prediction program 31, and a prediction explanation unit 42 is a functional unit that functions by the processor 11 executing the prediction explanation program 32.

The abnormality detection apparatus 1 reads the processing recipe data 21, the observation data 22, and the experimental result data 23 (S01). The data used in the training step is data for a case where the processing of the sample by the processing apparatus 2 is normally performed. Here, the expression that the processing of the sample is normal means that an evaluation value acquired as the experimental result data to be described later can be acquired from the sample after the processing. In the case of this embodiment, the evaluation value is the processing dimension of the sample.

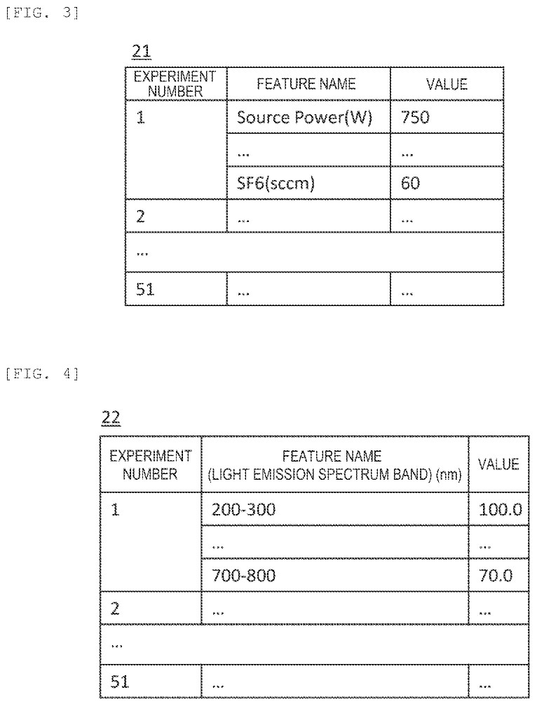

FIG. 3 shows a data structure example of the processing recipe data 21. An experiment number is a number for uniquely specifying processing (experiment) of the processing apparatus 2, a feature name is a control parameter of the processing apparatus 2, and a value is a value set for the control parameter in the experiment.

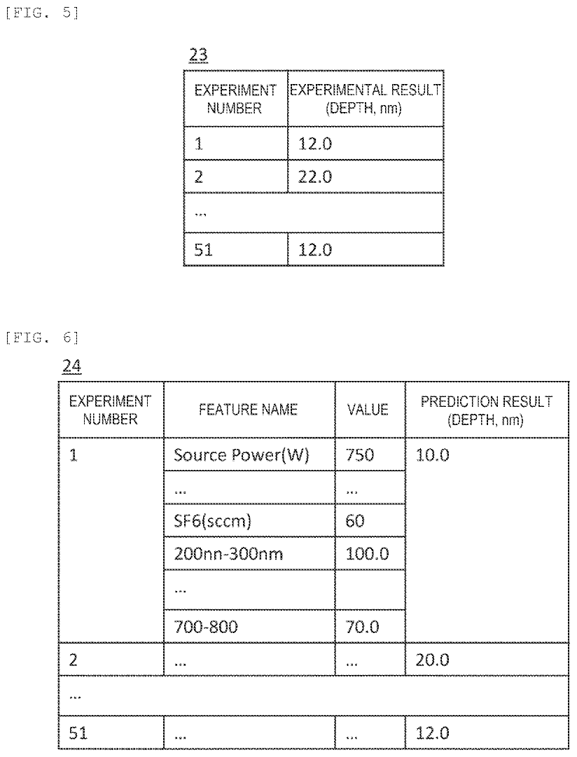

FIG. 4 shows a data structure example of the observation data 22. An experiment number is the same as the number in the processing recipe data 21. A feature name is an observation parameter in observation data acquired by the observation apparatus 4 during an experiment of the experiment number, and a value is a value of the observation parameter observed in the experiment. In the embodiment, an example is shown in which the observation parameter value is a light emission intensity in a predetermined band of plasma generated in the processing apparatus 2.

FIG. 5 shows a data structure example of the experimental result data 23. An experiment number is the same as the number in the processing recipe data 21. An experimental result shows an evaluation value obtained by the evaluation apparatus 5 with respect to a processing result obtained by an experiment of the experiment number. Here, an example is shown in which the evaluation value is a shape parameter value of the sample 3 processed by the processing apparatus 2, specifically, a processing depth.

Subsequently, the processing shape prediction unit 41 trains the processing shape prediction model based on the read processing recipe data 21, the read observation data 22, and the read experimental result data 23 (S02). The processing shape prediction model trained in step S02 is a model in which a dependent variable is a shape parameter value acquired as the experimental result data 23 and independent variables are a control parameter value acquired as the processing recipe data 21 and an observation parameter value acquired as the observation data 22. The processing shape prediction unit 41 executes supervised learning using the read normal case data as training data. The processing shape prediction model in this step can reflect a processing state of the processing apparatus 2 during the experiment in an inference of the dependent variable by including the observation parameter value as the independent variable.

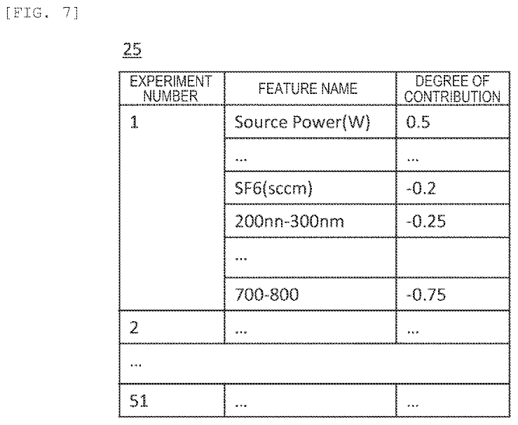

Further, the values of the processing recipe data 21 and the observation data 22 are input to the trained processing shape prediction model to obtain the prediction result data 24. FIG. 6 shows a data structure example of the prediction result data 24. An experiment number is the same as the number in the processing recipe data 21. A feature name includes the control parameter in the processing recipe data 21 and the observation parameter in the observation data 22, and a value indicates the control parameter value of the processing recipe data 21 and the observation parameter value of the observation data 22 in the experiment. As a prediction result, a shape parameter value obtained by substituting the control parameter value and the observation parameter value of the experiment number into the trained processing shape prediction model is registered. The shape parameter value calculated by the processing shape prediction model is a prediction value of the evaluation value (prediction evaluation value) defined in the experimental result data 23, and is the processing depth in this example.

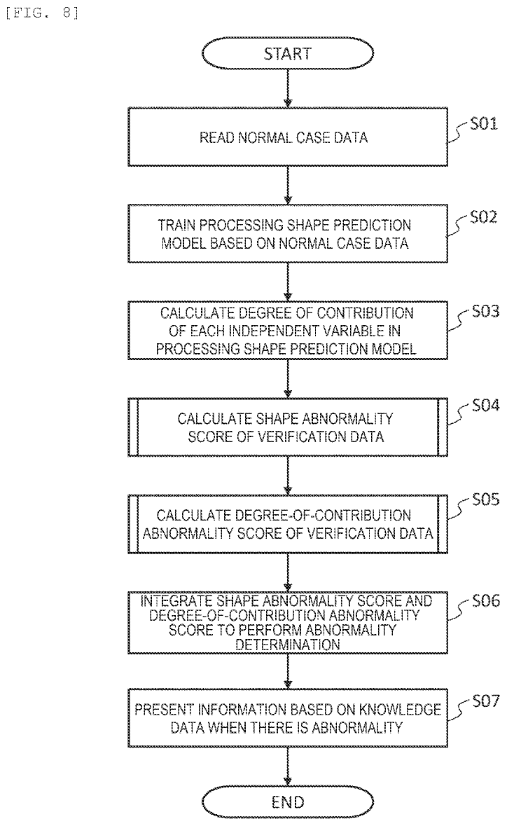

Subsequently, a degree of contribution of each independent variable in the trained processing shape prediction calculated (S03). The prediction explanation unit 42 interprets a basis on which the trained processing shape prediction model performs the prediction. Since contents of the processing shape prediction model, which is an AI model, are a black box, a reason why the prediction is obtained is unknown. Therefore, using an explainable AI (XAI) technique for interpreting the basis on which the AI model performs the prediction, the prediction explanation unit 42 calculates a degree of contribution indicating contribution of each independent variable to the prediction result (dependent variable) and accumulates the degree of contribution as the normal degree-of-contribution data 25. The degree of contribution of the independent variable in the normal case data is referred to as the normal degree of contribution. As a tool for performing such calculation, there is known a tool called Shapley additive explanations (SHAP). FIG. 7 shows a data structure example of the normal degree-of-contribution data 25. An experiment number is the same as the number in the processing recipe data 21. A feature name includes the control parameter and the observation parameter which are the independent variables in the processing shape prediction model, and in a degree of contribution, the degree of contribution of each independent variable to the prediction result (prediction result data 24) in the experiment is registered.

When the processing shape prediction model is updated by, for example, additional training, a value of the normal degree-of-contribution data 25 calculated by the prediction explanation unit 42 is also changed. Therefore, when the processing shape prediction model is updated by the processing shape prediction unit 41, the prediction explanation unit 42 recalculates the degree of contribution of the independent variable again in each experiment and updates the normal degree-of-contribution data 25.

### (2) Step of the Abnormality Detection of the Processing Result

Processing of steps S04 to S07 in the overall flow (see FIG. 8) will be described. FIG. 2B shows a functional block diagram of the abnormality detection apparatus 1 in this step. A shape abnormality detection unit 43 is a functional unit that functions by the processor 11 executing the shape abnormality detection program 33, a degree-of-contribution abnormality detection unit 44 is a functional unit that functions by the processor 11 executing the degree-of-contribution abnormality detection program 34, an integration determination unit 45 is a functional unit that functions by the processor 11 executing the integration determination program 35, and a knowledge linkage unit 46 is a functional unit that functions by the processor 11 executing the knowledge linkage program 36.

The shape abnormality detection unit 43 calculates a shape abnormality score of verification data (S04). Details of step S04 are shown in FIG. 9.

The abnormality detection apparatus 1 reads processing recipe data 51, observation data 52, and experimental result data 53, which are the verification data (S11). Such data corresponds to the processing recipe data 21 (see FIG. 3), the observation data 22 (see FIG. 4), and the experimental result data 23 (see FIG. 5) for one experiment.

Subsequently, the processing shape prediction unit 41 inputs the read processing recipe data 51 and the read observation data 52 to the trained processing shape prediction model to obtain prediction result data 54 (S12). The prediction result data 54 corresponds to the prediction result data 24 (see FIG. 6) for one experiment.

Subsequently, the shape abnormality detection unit 43 calculates a difference between the experimental result data 53 and the prediction result data 54 (S13), and calculates the shape abnormality score from a degree of the difference (S14). A method for calculating the shape abnormality score is not limited, and for example, the shape abnormality score is defined to increase as the difference between the experimental result data 53 and the prediction result data 54 increases.

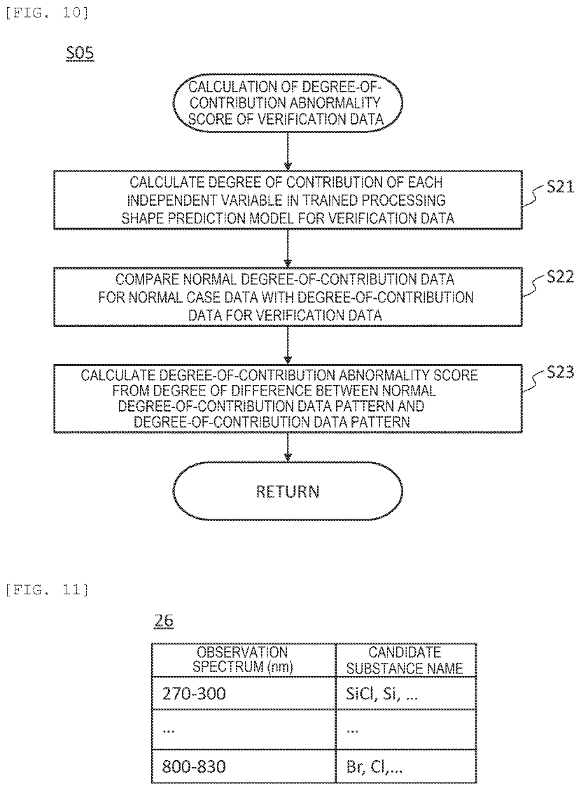

The description returns to the overall flow (FIG. 8). Subsequently, the degree-of-contribution abnormality detection unit 44 calculates a degree-of-contribution abnormality score of the verification data (S05). Details of step S05 are shown in FIG. 10.

First, the prediction explanation unit 42 calculates the degree of contribution of each independent variable in the trained processing shape prediction model to obtain degree-of-contribution data 55 (S21). The degree-of-contribution data 55 corresponds to the normal degree-of-contribution data 25 (see FIG. 7) for one experiment.

Subsequently, the degree-of-contribution abnormality detection unit 44 compares degree-of-contribution data in the normal case data stored in the normal degree-of-contribution data 25 with the degree-of-contribution data 55 (S22) and calculates the degree-of-contribution abnormality score from a degree of a difference between a normal degree-of-contribution data pattern and a degree-of-contribution data pattern (S23). A method for calculating the degree-of-contribution abnormality score is not limited, and for example, the degree-of-contribution abnormality score is defined to increase as the difference between the degree-of-contribution data pattern of the normal case data stored in the normal degree-of-contribution data 25 and the pattern of the degree-of-contribution data 55 increases.

The description returns to the overall flow (FIG. 8). Subsequently, the integration determination unit 45 integrates the shape abnormality score and the degree-of-contribution abnormality score to perform abnormality determination (S06). For example, the integration determination unit 45 performs determination as follows by combining the shape abnormality score and the degree-of-contribution abnormality score. When it is determined that the shape abnormality score is normal and the degree-of-contribution abnormality score is normal, it is determined that the processing result is normal. When it is determined that the shape abnormality score is normal and the degree-of-contribution abnormality score is abnormal, it is determined that the processing result is normal. This is to determine that a new degree-of-contribution pattern is found since the processing by the processing apparatus is correctly performed. When it is determined that the shape abnormality score is abnormal and the degree-of-contribution abnormality score is normal, it is determined that the processing result is normal. This is to determine that accuracy of the prediction model is insufficient since the processing by the processing apparatus is not performed as expected though the degree-of-contribution pattern is the same as the training data so far. When it is determined that the shape abnormality score is abnormal and the degree-of-contribution abnormality score is abnormal, it is determined that the processing result is abnormal. This is because there is a high possibility that an abnormality of the processing apparatus causes a shape abnormality and a degree-of-contribution abnormality.

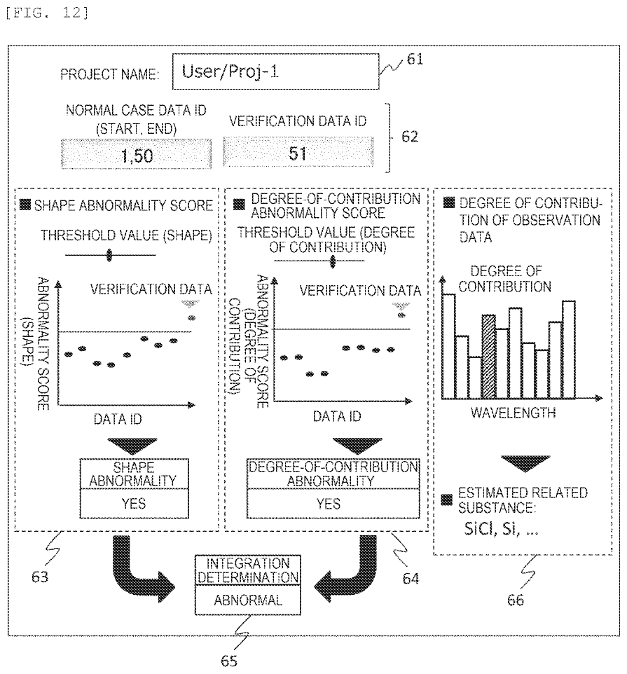

An experimental result determined to be normal by the integration determination unit 45 can be used, for example, as new training data to update the processing shape prediction model. On the other hand, for an experimental result determined to be abnormal by the integration determination unit 45, the knowledge linkage unit 46 may present information based on the knowledge data (S07). FIG. 11 shows a data structure example of the knowledge data 26. Contents of the knowledge may be any contents, and the knowledge is related to the observation parameter in the observation data 22. In the example in FIG. 11, a name of a causative substance that is a candidate when plasma light emission in a predetermined band is observed is stored.

For example, in the example in FIG. 11, when a degree-of-contribution abnormality is determined for observation data of a band of 270 nm to 300 nm in a light emission spectrum, it is presented to the user that SiCl, Si, and the like may be relevant as candidate substances. Accordingly, the user can easily examine a cause of the abnormality occurring in the processing apparatus.

Abnormality detection results of the shape abnormality detection unit 43 and the degree-of-contribution abnormality detection unit 44, a determination result of the integration determination unit 45, and knowledge extracted by the knowledge linkage unit 46 are displayed on the GUI as presentation information 56.

FIG. 12 shows an example of the GUI for executing the processing in FIG. 8. A project specifying unit 61 specifies, for example, a project name for specifying creation of the processing shape prediction model for determining the processing condition of the processing apparatus 2. The processing recipe data 21, the observation data 22, and the experimental result data 23 are linked to the project name. A data specifying unit 62 specifies a normal case data ID (a data ID corresponds to the experiment number) and a verification data ID (a data ID corresponds to the experiment number). For example, in the present project, first, a provisional processing shape prediction model is created, and thereafter, normality or abnormality of an experimental result is determined based on the provisional processing shape prediction model, it is determined whether to adopt the experimental result as training data, and the provisional processing shape prediction model is updated by training data determined to be normal. Accordingly, it is possible to generate a highly accurate processing shape prediction model with less training data. In this example, an example is shown in which experiment numbers 1 to 50 in the processing recipe data 21, the observation data 22, and the experimental result data 23 are used to generate the provisional processing shape prediction model, and the experiment number 51 is a determination target whose addition as training data is to be determined.

A shape abnormality score display unit 63 displays the processing result in step S04 (see FIG. 8), a degree-of-contribution abnormality score display unit 64 displays the processing result in step S05, an integration determination display unit 65 displays the processing result in step S06, and a knowledge display unit 66 displays the knowledge extracted in step S07.

The shape abnormality score display unit 63 and the degree-of-contribution abnormality score display unit 64 display an abnormality score value and a threshold value of each of the normal case and the verification data. The threshold value may be set by the user or may be automatically set statistically. For example, the threshold value can be defined as a value obtained by adding twice a variance to an average value of abnormality scores in the normal case, that is, the training data of the processing shape prediction model. The threshold value may be changed according to improvement in accuracy of the processing shape prediction model.

On the knowledge display unit 66, the observation parameter (here, a wavelength of a light emission spectrum) where an abnormal value is detected in a degree of contribution in the observation data is identifiably displayed, and the knowledge extracted in step S07 is displayed.

Although an example in which the disclosed technique is applied to the creation step of the processing shape prediction model is described as the embodiment, the invention is not limited thereto. For example, after the training of the processing shape prediction model is completed, it is also possible to monitor by calculating the degree-of-contribution abnormality score regarding whether a processing abnormality of the processing apparatus occurs in mass production of the semiconductor sample for which the condition is set based on the model.

As an aspect of the embodiment described above, a semiconductor apparatus manufacturing system is conceivable in which an application for operating and managing a line including a semiconductor processing apparatus is executed on a platform. The semiconductor processing apparatus is connected to the platform via a network and is controlled by the platform. In this case, the embodiment can be implemented in the semiconductor apparatus manufacturing system by using the abnormality detection apparatus 1 as the application on the platform to execute processing.

### REFERENCE SIGNS LIST

1: abnormality detection apparatus
2: processing apparatus
2a: reactor
2b: control unit
3: sample
4: observation apparatus
5: evaluation apparatus
6: network
7: terminal
11: processor (CPU)
12: memory
13: storage apparatus
14: input apparatus
15: output apparatus
16: communication apparatus
17: bus
21: processing recipe data
22: observation data
23: experimental result data
24: prediction result data
25: normal degree-of-contribution data
26: knowledge data
31: processing shape prediction program
32: prediction explanation program
33: shape abnormality detection program
34: degree-of-contribution abnormality detection program
35: integration determination program
36: knowledge linkage program
41: processing shape prediction unit
42: prediction explanation unit
43: shape abnormality detection unit
44: degree-of-contribution abnormality detection unit
45: integration determination unit
46: knowledge linkage unit
51: processing recipe data
52: observation data
53: experimental result data
54: prediction result data
55: degree-of-contribution data
56: presentation information
61: project specifying unit
62: data specifying unit
63: shape abnormality score display unit
64: degree-of-contribution abnormality score display unit
65: integration determination display unit
66: knowledge display unit

1. An abnormality detection apparatus for determining whether there is an abnormality in a processing result obtained by processing a sample by a processing apparatus, the abnormality detection apparatus comprising:
a processing shape prediction unit configured to predict, using a processing result prediction model in which a control parameter value of the processing apparatus and an observation parameter value obtained by observing a phenomenon occurring in the processing apparatus during the processing by the processing apparatus are set as an independent variable and an evaluation value of the processing by the processing apparatus is set as a dependent variable, the evaluation value of the processing by the processing apparatus; and
a first abnormality detection unit configured to detect, based on a difference between an evaluation value of determination target processing and a prediction evaluation value of the determination target processing predicted by inputting a control parameter value used in the determination target processing and an observation parameter value observed in the determination target processing to the processing result prediction model, an abnormality in the processing result of the processing apparatus.

2. The abnormality detection apparatus according to claim 1, further comprising:
a prediction explanation unit configured to calculate a degree of contribution of each independent variable to the prediction evaluation value for the determination target processing; and
a second abnormality detection unit configured to detect, based on a degree-of-contribution pattern of the independent variable in the determination target processing calculated by the prediction explanation unit, the abnormality in the processing result of the processing apparatus.

3. The abnormality detection apparatus according to claim 2, further comprising:
integration determination unit configured to integrate an abnormality detection result of the first abnormality detection unit and an abnormality detection result of the second abnormality detection unit to determine whether there is an abnormality in a result of the determination target processing.

4. The abnormality detection apparatus according to claim 3, wherein
the processing result prediction model is trained based on a plurality of results of an experiment obtained by processing the sample by the processing apparatus,
the abnormality detection apparatus further comprises a storage apparatus configured to store a control parameter value used in processing in the experiment, an observation parameter value observed in the processing in the experiment, and an evaluation value of the processing in the experiment, which are used as training data of the processing result prediction model, and
the first abnormality detection unit detects the abnormality in the processing result of the processing apparatus by comparing a difference between the evaluation value and the prediction evaluation value of the determination target processing with a difference between the evaluation value of the processing in the experiment and a prediction evaluation value of the processing in the experiment predicted by inputting the control parameter value used in the processing in the experiment and the observation parameter value observed in the processing in the experiment to the processing result prediction model.

5. The abnormality detection apparatus according to claim 4, wherein
the prediction explanation unit calculates a degree of contribution of each independent variable to the prediction evaluation value for the processing in the experiment, and stores, in the storage apparatus, a degree-of-contribution pattern of the independent variable in the processing in the experiment calculated by the prediction explanation unit, and
the second abnormality detection unit detects the abnormality in the processing result of the processing apparatus by comparing the degree-of-contribution pattern of the independent variable in the determination target processing with the degree-of-contribution pattern of the independent variable in the processing in the experiment.

6. The abnormality detection apparatus according to claim 5, wherein
the processing shape prediction unit trains the processing result prediction model using the training data stored in the storage apparatus.

7. The abnormality detection apparatus according to claim 6, wherein
when the integration determination unit determines that there is no abnormality in the result of the determination target processing, the processing shape prediction unit trains the processing result prediction model using the evaluation value of the determination target processing, the control parameter value used in the determination target processing, and the observation parameter value observed in the determination target processing, and
the integration determination unit determines that there is an abnormality in the result of the determination target processing when both the first abnormality detection unit and the second abnormality detection unit detect an abnormality, and determines that there is no abnormality in the result of the determination target processing when at least one of the first abnormality detection unit and the second abnormality detection unit does not detect the abnormality.

8. The abnormality detection apparatus according to claim 7, further comprising:
a knowledge linkage unit configured to, when the integration determination unit determines that there is an abnormality in the result of the determination target processing, match an observation parameter value whose abnormality is detected by the second abnormality detection unit with knowledge data and to extract related knowledge.

9. The abnormality detection apparatus according to claim 8, wherein
the abnormality detection results of the first abnormality detection unit and the second abnormality detection unit, a result of the determination by the integration determination unit, and the knowledge extracted by the knowledge linkage unit are displayed on a display apparatus.

10. The abnormality detection apparatus according to claim 1, wherein
the processing apparatus is a plasma processing apparatus configured to etch the sample, and
a light emission intensity of plasma in a predetermined band obtained by observing light emission of the plasma generated in the processing apparatus during processing by the processing apparatus is set as the observation parameter value, and a processing dimension of the sample by the etching is set as the evaluation value of the processing by the processing apparatus.

11. An abnormality detection method using an abnormality detection apparatus for determining whether there is an abnormality in a processing result obtained by processing a sample by a processing apparatus, the abnormality detection apparatus including a processing shape prediction unit and a first abnormality detection unit, the method comprising:
causing the processing shape prediction unit to predict, using a processing result prediction model in which a control parameter value of the processing apparatus and an observation parameter value obtained by observing a phenomenon occurring in the processing apparatus during the processing by the processing apparatus are set as an independent variable and an evaluation value of the processing by the processing apparatus is set as a dependent variable, the evaluation value of the processing by the processing apparatus; and
causing the first abnormality detection unit to detect, based on a difference between an evaluation value of determination target processing and a prediction evaluation value of the determination target processing predicted by inputting a control parameter value used in the determination target processing and an observation parameter value observed in the determination target processing to the processing result prediction model, an abnormality in the processing result of the processing apparatus.

12. The abnormality detection method according to claim 11, wherein
the abnormality detection apparatus further includes a prediction explanation unit and a second abnormality detection unit, and
the method further comprises:
causing the prediction explanation unit to calculate a degree of contribution of each independent variable to the prediction evaluation value for the determination target processing; and
causing the second abnormality detection unit to detect, based on a degree-of-contribution pattern of the independent variable in the determination target processing calculated by the prediction explanation unit, the abnormality in the processing result of the processing apparatus.

13. The abnormality detection method according to claim 12, wherein
the abnormality detection apparatus further includes an integration determination unit, and
the method further comprises: causing the integration determination unit to integrate an abnormality detection result of the first abnormality detection unit and an abnormality detection result of the second abnormality detection unit to determine whether there is an abnormality in a result of the determination target processing.

14. The abnormality detection method according to claim 13, wherein
when the integration determination unit determines that there is no abnormality in the result of the determination target processing, the processing shape prediction unit trains the processing result prediction model using the evaluation value of the determination target processing, the control parameter value used in the determination target processing, and the observation parameter value observed in the determination target processing, and
the integration determination unit determines that there is an abnormality in the result of the determination target processing when both the first abnormality detection unit and the second abnormality detection unit detect an abnormality, and determines that there is no abnormality in the result of the determination target processing when at least one of the first abnormality detection unit and the second abnormality detection unit does not detect the abnormality.

15. The abnormality detection method according to claim 11, wherein
the processing apparatus is a plasma processing apparatus configured to etch the sample, and
a light emission intensity of plasma in a predetermined band obtained by observing light emission of the plasma generated in the processing apparatus during processing by the processing apparatus is set as the observation parameter value, and a processing dimension of the sample by the etching is set as the evaluation value of the processing by the processing apparatus.
